(19) United States
(12) Patent Application Publication
(10) Pub. No.: US 2024/0304568 A1
(43) Pub. Date: Sep. 12, 2024

(54) SEMICONDUCTOR DEVICE

(71) Applicant: SAMSUNG ELECTRONICS CO., LTD., SUWON-SI (KR)

(72) Inventors: Inyeal Lee, Suwon-si (KR); Younghoi Kim, Suwon-si (KR); Juyoun Kim, Suwon-si (KR); Jaekang Park, Suwon-si (KR)

(21) Appl. No.: 18/595,666

(22) Filed: Mar. 5, 2024

(30) Foreign Application Priority Data
Mar. 6, 2023 (KR) 10-2023-0029275

(51) Int. Cl. H01L 23/00; H01L 21/8238; H01L 27/092

(52) U.S. Cl. CPC H01L 23/562; H01L 21/823878; H01L 27/092

(57) ABSTRACT

A semiconductor device includes a semiconductor substrate, a plurality of gate structures which are spaced apart from each other in a first horizontal direction on the semiconductor substrate and extend in a second horizontal direction perpendicular to the first horizontal direction, and a single diffusion brake which extends in the second horizontal direction between the plurality of gate structures and is located in a first trench having a first depth in a vertical direction. The single diffusion brake includes a lower insulating material film conformally disposed on a side wall of the first trench, an insulating liner extending onto upper surfaces of the plurality of gate structures along an inner wall of the lower insulating material film, and an upper insulating material film disposed on the insulating liner and filling the inside of the first trench.

### CROSS-REFERENCE TO RELATED APPLICATION

This application is based on and claims priority under 35 U.S.C. § 119 to Korean Patent Application No. 10-2023-0029275, filed on Mar. 6, 2023, in the Korean Intellectual Property Office, the disclosure of which is incorporated by reference herein in its entirety.

### BACKGROUND

The inventive concept relates to a semiconductor device, and more particularly, to a semiconductor device including a single diffusion brake.

Semiconductor devices have been able to have a high degree of integration due to the development of semiconductor processes and may have resulting higher performance. For example, small-sized semiconductor devices may reduce the area of an integrated circuit, and large-sized semiconductor devices may be advantageous in improving the operating speed of the integrated circuit. Therefore, in order to achieve the functions and operating speed required for an integrated circuit, it can be important to design semiconductor devices considering both the degree of integration and performance.

### SUMMARY

The inventive concept provides a semiconductor device capable of stress modulation by selectively controlling a material that fills the inside of a single diffusion brake.

The objects of the inventive concept are not limited to the object mentioned above, but other aspects not described herein can be clearly understood by those skilled in the art from the following description.

According to an aspect of the inventive concept, there is provided a semiconductor device including a semiconductor substrate, a plurality of gate structures which are spaced apart from each other in a first horizontal direction on the semiconductor substrate and extend in a second horizontal direction perpendicular to the first horizontal direction, and a single diffusion brake which extends in the second horizontal direction between the plurality of gate structures and is located in a first trench having a first depth in a vertical direction, wherein the single diffusion brake includes a lower insulating material film on a side wall of the first trench, an insulating liner extending onto upper surfaces of the plurality of gate structures along an inner wall of the lower insulating material film, and an upper insulating material film on the insulating liner and filling an inside of the first trench.

According to another aspect of the inventive concept, there is provided a semiconductor device including a semiconductor substrate, a plurality of gate structures which are spaced apart from each other in a first horizontal direction on the semiconductor substrate and extend in a second horizontal direction perpendicular to the first horizontal direction, and a single diffusion brake which extends in the second horizontal direction between the plurality of gate structures and is located in a first trench having a first depth in a vertical direction, wherein the single diffusion brake includes a lower insulating material film on a side wall of the first trench, insulating liners stacked in at least two layers and extending onto upper surfaces of the plurality of gate structures along an inner wall of the lower insulating material film, and an upper insulating material film on the insulating liners and filling an inside of the first trench.

According to another aspect of the inventive concept, there is provided a semiconductor device including a semiconductor substrate, a plurality of active patterns extending in a first horizontal direction in the semiconductor substrate, a plurality of gate structures which extend in a second horizontal direction perpendicular to the first horizontal direction, wherein the plurality of gate structures cross the plurality of active patterns in the semiconductor substrate, a gate cut structure configured to cut portions of the plurality of gate structures in the semiconductor substrate, and a single diffusion brake which extends between the plurality of gate structures in the second horizontal direction and is located in a first trench having a first depth in a vertical direction, wherein the single diffusion brake includes a lower insulating material film on a side wall of the first trench, an insulating liner extending onto both upper surfaces of the plurality of gate structures and an upper surface of the gate cut structure along an inner wall of the lower insulating material film, and an upper insulating material film on the insulating liner and filling an inside of the first trench.

### BRIEF DESCRIPTION OF THE DRAWINGS

Embodiments will be more clearly understood from the following detailed description taken in conjunction with the accompanying drawings in which:

FIG. 1 is a schematic layout showing a semiconductor device according to an embodiment;

FIG. 2 is a cross-sectional view taken along line X-X′ of FIG. 1;

FIGS. 3 and 4 are cross-sectional views showing semiconductor devices according to some embodiments;

FIG. 5 is a flowchart showing a method of manufacturing a semiconductor device according to an embodiment;

FIGS. 6 to 16 are cross-sectional views showing a method of manufacturing a semiconductor device in a process sequence, according to an embodiment;

FIG. 17 is a schematic perspective view showing a semiconductor device according to an embodiment;

FIGS. 18 and 19 are cross-sectional views corresponding to an active pattern of the semiconductor device of FIG. 17; and

FIG. 20 is a block diagram showing a system including a semiconductor device according to an embodiment.

### DETAILED DESCRIPTION OF THE EMBODIMENTS

Hereinafter, an embodiment is described in detail with reference to the accompanying drawings.

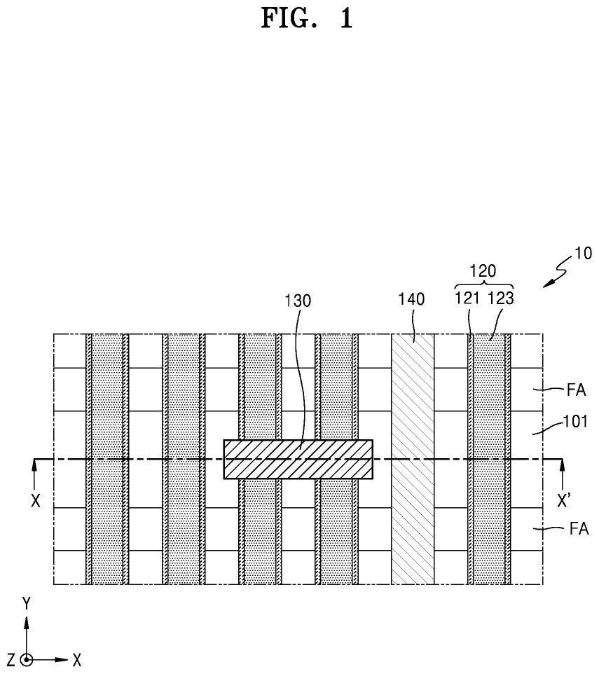

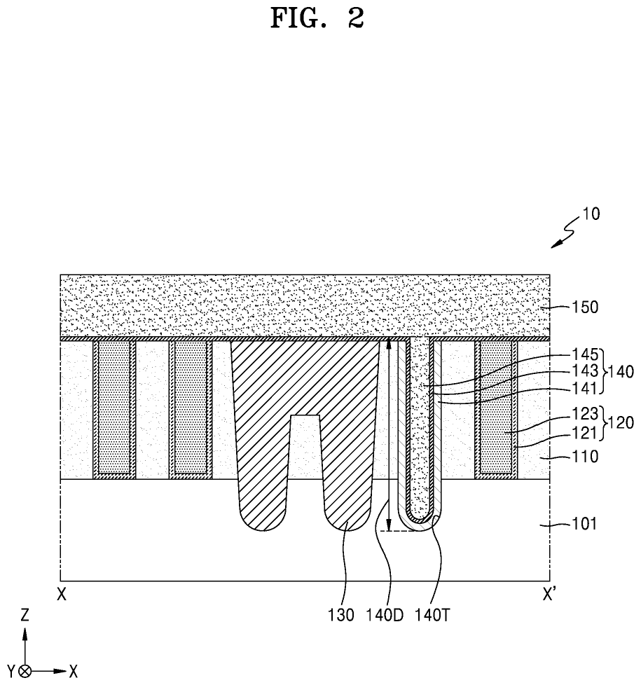

FIG. 1 is a schematic layout showing a semiconductor device 10 according to an embodiment, and FIG. 2 is a cross-sectional view taken along line X-X′ of FIG. 1. For convenience of description, some components of FIG. 2 are shown transparently in FIG. 1.

Referring to FIGS. 1 and 2 together, provided is the semiconductor device 10 that includes a lower interlayer insulating film 110, a plurality of gate structures 120, a gate cut structure 130, a single diffusion brake 140, and an upper interlayer insulating film 150, which are arranged above a semiconductor substrate 101.

The semiconductor substrate 101 may include a wafer that contains silicon (Si). In some embodiments, the semiconductor substrate 101 may include a wafer that contains a semiconductor element, such as germanium (Ge), or a compound semiconductor, such as silicon carbide (SiC), gallium arsenide (GaAs), indium arsenide (InAs), and indium phosphide (InP). Here, the semiconductor substrate 101 may have a silicon on insulator (SOI) structure. Also, the semiconductor substrate 101 may include a conductive region, for example, a well doped with impurities or a structure doped with impurities.

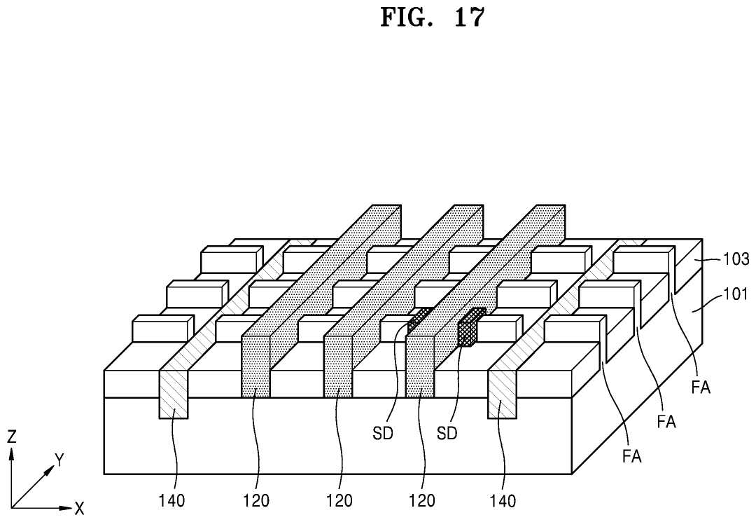

The lower interlayer insulating film 110 may be disposed on a source/drain region SD (see FIG. 17) and a device isolation film 103 (see FIG. 17). In addition, the lower interlayer insulating film 110 may be in contact with outer walls of the plurality of gate structures 120, where the gate structures 120 may include multiple layers. The lower interlayer insulating film 110 may include, for example, at least one of silicon oxide, silicon nitride, silicon oxynitride, or a low-k dielectric material, as an insulating material. The lower interlayer insulating film 110 may be a silicon nitride film.

The plurality of gate structures 120 may be spaced apart from each other in a first horizontal direction (X direction) on the semiconductor substrate 101 and extend in a second horizontal direction (Y direction), where the second horizontal direction (Y direction) can be perpendicular to the first horizontal direction (X direction). Also, the plurality of gate structures 120 may be arranged on an active pattern FA and the device isolation film 103. Each of the plurality of gate structures 120 may include a gate dielectric film 121, a gate electrode 123, and a gate capping film.

The gate dielectric film 121 may be disposed between the gate electrode 123 and the active pattern FA. Also, the gate dielectric film 121 may be disposed between the gate electrode 123 and the lower interlayer insulating film 110. The gate dielectric film 121 may be disposed between the gate electrode 123 and the semiconductor substrate 101. The gate dielectric film 121 may extend in the second horizontal direction (Y direction) along a profile of the active pattern FA that protrudes above the device isolation film 103. In some embodiments, the gate dielectric film 121 and the gate electrode 123 may be formed by a replacement process or a gate last process. The gate dielectric film 121 may include a high-k dielectric material having a higher dielectric constant than silicon oxide. For example, the gate dielectric film 121 may include HfO₂, ZrO₂, LaO, Al₂O₃, Ta₂O₅, or the like.

The gate electrode 123 may have a single layer or a multilayer structure in which two or more layers are stacked. In some embodiments, the gate electrode 123 may include a work-function control layer and a central electrode layer. The work-function control layer may control a work function of the gate structure 120, and the central electrode layer may fill a space formed by the work-function control layer, where the work-function control layer can separate the central electrode layer from the gate dielectric film 121. The work-function control layer may include, for example, at least one of TIN, WN, TiAl, TiAlN, TaN, TIC, TaC, TaCN, TaSiN, or a combination thereof. In addition, the central electrode layer may include, for example, at least one of W, Al, Co, Ti, Ta, poly-Si, SiGe, or a metal alloy.

In various embodiments, the gate capping film may extend in the second horizontal direction (Y direction) on an upper surface the gate electrode 123. The gate capping film may include, for example, at least one of silicon nitride, silicon oxynitride, or silicon oxycarbonitride.

The source/drain region SD may be disposed on both sides of each of the plurality of gate structures 120. The source/drain region SD may be located inside the active pattern FA, where the source/drain region SD may be formed in a region in which the active pattern FA is partially etched. In some embodiments, the source/drain region SD may include a raised source/drain region. Accordingly, an upper end of the source/drain region SD may be higher than an upper end of the active pattern FA (see FIG. 17).

In some embodiments, when the semiconductor device 10 includes a p-channel metal-oxide semiconductor (PMOS) transistor, the source/drain region SD may include a compressive strain material. The compressive strain material may include a material having a greater lattice constant than silicon (Si) and may include, for example, silicon germanium (SiGe). The compressive strain material may improve carrier mobility in a channel region by applying tensile stress to the active pattern FA under the plurality of gate structures 120. In some embodiments, when the semiconductor device 10 includes an n-channel metal-oxide semiconductor (NMOS) transistor, the source/drain region SD may include the same material as the semiconductor substrate 101 or a tensile strain material. The tensile strain material may include a material having a lower lattice constant than silicon (Si) and may include, for example, silicon carbide (SiC). The tensile strain material may improve carrier mobility in a channel region by applying compressive stress to the active pattern FA under the plurality of gate structures 120.

The gate cut structure 130 may extend lengthwise in the first horizontal direction (X direction), so as to intersect a plurality of gate structures 120 (see FIG. 1). A pair of gate structures 120, which are adjacent to each other in the second horizontal direction (Y direction) and disposed on both sides of the gate cut structure 130 with the gate cut structure 130 therebetween, may not be connected to but spaced apart from each other. The gate structures 120, which are arranged in a line in the second horizontal direction (Y direction) among the plurality of gate structures 120, may be spaced apart from each other by the gate cut structure 130. In addition, a length, in the second horizontal direction (Y direction), of at least one gate structure 120 among the plurality of gate structures 120 may be limited by the gate cut structure 130, where a gate structure 120 may end at the gate cut structure 130.

The gate cut structure 130 may include an insulating material. In some embodiments, the gate cut structure 130 may include silicon nitride (SiN), silicon oxide (SiO), silicon oxynitride (SiON), etc., but the embodiment is not limited thereto.

The single diffusion brake 140 may be located between an adjacent pair of gate structures 120. In the semiconductor device 10, a standard cell represents a unit of a layout included in an integrated circuit. A boundary of the standard cell may be determined by a cell separation film. The cell separation film may be inserted between standard cells in order to reduce an effect between neighboring standard cells, for example, a local layout effect (LLE) therebetween. The cell separation film may separate the active pattern FA between neighboring cells and may be filled with an insulating material. In some embodiments, as at least a portion of the source/drain region SD and/or the active pattern FA is removed, the cell separation film may separate the source/drain region SD between neighboring cells. In various embodiments, the cell separation film may be a single diffusion brake 140, where the diffusion break can provide both electrical and chemical isolation between neighboring cells.

The single diffusion brake 140 passes through the lower interlayer insulating film 110 and may extend, by a first depth 140D, in a vertical direction (Z direction), so as to fill a first trench 140T that extends into the semiconductor substrate 101, where a level of a lowermost surface of the first trench 140T can be lower than a level of an upper surface of the semiconductor substrate 101. The vertical direction (Z direction) can be perpendicular to the first horizontal direction (X direction) and the second horizontal direction (Y direction). In some embodiments, the single diffusion brake 140 may be formed at a position, at which the gate structure 120 is located, through a replacement process, in order to separate the source/drain region SD between neighboring cells.

In the semiconductor device 10 according to the embodiment, the single diffusion brake 140 may include a lower insulating material film 141 conformally disposed on the inner wall of the first trench 140T, an insulating liner 143 extending onto upper surfaces of the plurality of gate structures 120 along an inner wall of the lower insulating material film 141, and an upper insulating material film 145 disposed on the insulating liner 143 and filling the inside of the first trench 140T.

Here, the insulating liner 143 may be formed to be substantially flat on both the upper surfaces of the plurality of gate structures 120 and/or the upper surface of the gate cut structure 130 and may have a U-shape inside the first trench 140T.

Specifically, the inner wall of the first trench 140T may be in contact with the lower insulating material film 141. The lower insulating material film 141 can conform to the shape of the first trench 140T, and may have a U-shape inside the first trench 140T, where a bottom surface of a U-shaped, first trench 140T may be lower than an upper surface of the semiconductor substrate 101. The inner wall and the upper surface of the lower insulating material film 141 may be in contact with the insulating liner 143, where the insulating liner 143 can conform to the shape of the lower insulating material film 141. The inner wall and the upper surface of the insulating liner 143 may be in contact with the upper insulating material film 145, where the insulating liner 143 can separate the upper insulating material film 145 from the lower insulating material film 141. The lower surface of the insulating liner 143 may be in contact with both the upper surfaces of the plurality of gate structures 120 and the upper surface of the gate cut structure 130.

Each of the lower insulating material film 141, the insulating liner 143, and the upper insulating material film 145 may include, for example, silicon nitride (SiN), silicon carbonitride (SiCN), silicon oxide (SiO), silicon oxynitride (SiON), silicon carbide (SiC), silicon oxycarbide (SiOC), silicon oxycarbonitride (SiOCN), silicon boron nitride (SiBN), silicon boron carbon nitride (SiBCN), titanium oxide (TiO), or boron nitride (BN), but the embodiment is not limited thereto.

In some embodiments, the lower insulating material film 141, the insulating liner 143, and the upper insulating material film 145 may each include different materials, but the embodiment is not limited thereto. For example, the lower insulating material film 141 may include a nitride film-based material, the insulating liner 143 may include a carbide film-based material, and the upper insulating material film 145 may include an oxide film-based material. For example, the lower insulating material film 141 may be a silicon nitride film, and the upper insulating material film 145 may be a silicon oxide film.

The upper interlayer insulating film 150 may be disposed on the insulating liner 143 and the upper insulating material film 145. In addition, the upper interlayer insulating film 150 may be provided in the form continuously connected to the upper insulating material film 145. Accordingly, the upper interlayer insulating film 150 may include substantially the same material as the upper insulating material film 145.

In various embodiments, the single diffusion brake 140 may include one type of the same material. This structure is effective in simplifying a manufacturing process of the single diffusion brake 140, but has difficulties in planarization for a metal wiring process of a middle end of line, which is a subsequent process. In addition, as an aspect ratio of the single diffusion brake 140 increases, stress is applied to transistors positioned around the single diffusion brake 140. This affects the mechanical and electrical stability of the semiconductor device 10.

Accordingly, the semiconductor device 10 according to the inventive concept is configured such that the single diffusion brake 140 has a multilayer structure therein. Therefore, stress modulation is possible by selectively controlling materials that constitute the multilayer structure, and thus, there is an effect of providing high mechanical stability and high electrical stability.

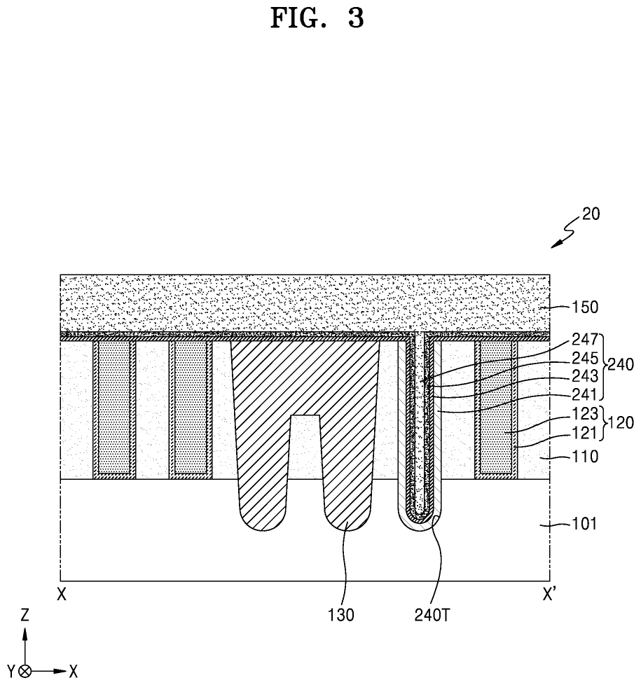

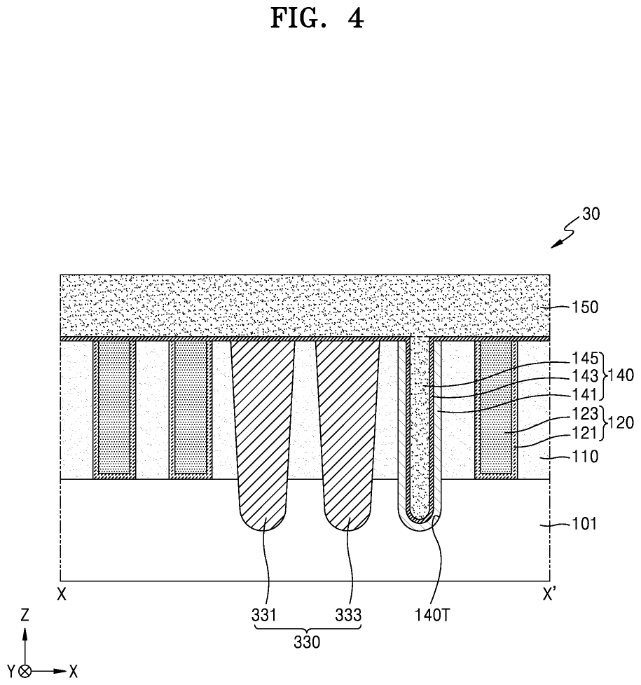

FIGS. 3 and 4 are cross-sectional views showing semiconductor devices 20 and 30 according to some embodiments.

Most of components constituting the semiconductor devices 20 and 30 described below and materials constituting the components are substantially the same as or similar to those described above with reference to FIGS. 1 and 2. Therefore, for convenience of description, the description focuses on differences from the semiconductor device 10 described above.

Referring to FIG. 3, provided is a semiconductor device 20 that includes a lower interlayer insulating film 110, a plurality of gate structures 120, a gate cut structure 130, a single diffusion brake 240, and an upper interlayer insulating film 150, which are arranged above a semiconductor substrate 101.

In the semiconductor device 20 according to the embodiment, the single diffusion brake 240 may include a lower insulating material film 241 conformally disposed on a side wall of a first trench 240T, first insulating liner 243 and second insulating liner 245 stacked in at least two layers and extending onto the upper surfaces of the plurality of gate structures 120 along an inner wall of the lower insulating material film 241, and an upper insulating material film 247, which is disposed on the first and second insulating liners 243 and 245 stacked on each other and fills the inside of the first trench 240T. The second insulating liner 245 can be between the first insulating liner 243 and the upper insulating material film 247, where the upper insulating material film 247 can be in direct contact with the second insulating liner 245. The insulating liners may be stacked in at least two layers, and extend onto upper surfaces of the plurality of gate structures 120 along an inner wall of the lower insulating material film 241.

In various embodiments, the first and second insulating liners 243 and 245 may include the first insulating liner 243 located in a lower region and the second insulating liner 245 located in an upper region. Each of the first insulating liner 243 and the second insulating liner 245 may be substantially flat on the upper surfaces of the plurality of gate structures 120 and the upper surface of the gate cut structure 130, where the first insulating liner 243 and the second insulating liner 245 may have a U-shape inside the first trench 240T.

Specifically, the inner wall of the first trench 240T may be in contact with the lower insulating material film 241, the inner wall and upper surface of the lower insulating material film 241 may be in contact with the first insulating liner 243, the inner wall and upper surface of the first insulating liner 243 may be in contact with the second insulating liner 245, and the inner wall and upper surface of the second insulating liner 245 may be in contact with the upper insulating material film 247. Accordingly, the lower surface of the first insulating liner 243 may be in contact with both the upper surfaces of the plurality of gate structures 120 and the upper surface of the gate cut structure 130.

Each of the lower insulating material film 241, the first insulating liner 243, the second insulating liner 245, and the upper insulating material film 247 may include, for example, silicon nitride (SiN), silicon carbonitride (SiCN), silicon oxide (SiO), silicon oxynitride (SiON), silicon carbide (SiC), silicon oxycarbide (SiOC), silicon oxycarbonitride (SiOCN), silicon boron nitride (SiBN), silicon boron carbon nitride (SiBCN), titanium oxide (TiO), or boron nitride (BN), but the embodiment is not limited thereto.

In some embodiments, the lower insulating material film 241, the first insulating liner 243, the second insulating liner 245, and the upper insulating material film 247 may include different materials, but the embodiment is not limited thereto. For example, the lower insulating material film 241 may include a nitride film-based material, each of the first insulating liner 243 and the second insulating liner 245 may include a carbide film-based material, and the upper insulating material film 247 may include an oxide film-based material. The first insulating liner 243 located in a lower region and the second insulating liner 245 located in an upper region.

The upper interlayer insulating film 150 may be disposed on the second insulating liner 245 and the upper insulating material film 247. In addition, the upper interlayer insulating film 150 may be provided continuously connected to the upper insulating material film 247. Accordingly, the upper interlayer insulating film 150 may include substantially the same material as the upper insulating material film 247.

Referring to FIG. 4, provided is a semiconductor device 30 that includes a lower interlayer insulating film 110, a plurality of gate structures 120, a gate cut structure 330, a single diffusion brake 140, and an upper interlayer insulating film 150, which are arranged above a semiconductor substrate 101.

In the semiconductor device 30 according to the embodiment, the gate cut structure 330 may include a first gate cut structure 331 and a second gate cut structure 333, which are adjacent to each other. The first gate cut structure 331 and the second gate cut structure 333 may extend lengthwise in a first horizontal direction (X direction), so as to cross the plurality of gate structures 120. A pair of gate structures 120, which are adjacent to each other in a second horizontal direction (Y direction) and disposed on both sides of the first gate cut structure 331 and the second gate cut structure 333 with the first gate cut structure 331 and the second gate cut structure 333 therebetween, may not be connected to but spaced apart from each other. The first horizontal direction (X direction) can be perpendicular to the second horizontal direction (Y direction).

A plurality of gate structures 120, which are arranged in a line in the second horizontal direction (Y direction) among the plurality of gate structures 120, may be spaced apart from each other by the first gate cut structure 331 and the second gate cut structure 333. In addition, a length, in the second horizontal direction (Y direction), of at least one gate structure 120 among the plurality of gate structures 120 may be limited by the first gate cut structure 331 or the second gate cut structure 333, where a gate structure 120 may end at the first gate cut structure 331 or the second gate cut structure 333.

Each of the first gate cut structure 331 and the second gate cut structure 333 may include an insulating material. In some embodiments, each of the first gate cut structure 331 and the second gate cut structure 333 may include silicon nitride (SiN), silicon oxide (SiO), silicon oxynitride (SiON), or the like, but the embodiment is not limited thereto.

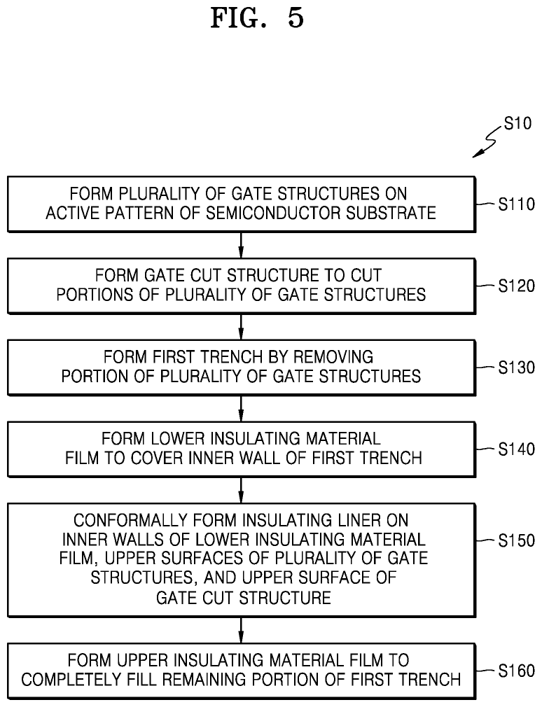

FIG. 5 is a flowchart showing a method of manufacturing a semiconductor device, according to an embodiment.

Referring to FIG. 5, a method S10 of manufacturing a semiconductor device may include first to sixth operations S110 to S160.

When an embodiment can be implemented differently, a specific process order may be performed in a different manner from the described order. For example, two consecutively described processes may be performed substantially at the same time or performed in an order opposite to the described order.

The method S10 of manufacturing a semiconductor device, according to the inventive concept, may include: a first operation S110 of forming a plurality of gate structures on an active pattern of a semiconductor substrate; a second operation S120 of forming a gate cut structure to cut portions of the plurality of gate structures; a third operation S130 of forming a first trench by removing a portion of the plurality of gate structures; a fourth operation S140 of forming a lower insulating material film to cover an inner wall of the first trench; a fifth operation S150 of conformally forming an insulating liner on inner walls of the lower insulating material film, upper surfaces of the plurality of gate structures, and an upper surface of the gate cut structure; and a sixth operation S160 of forming an upper insulating material film to fill the remaining portion of the first trench.

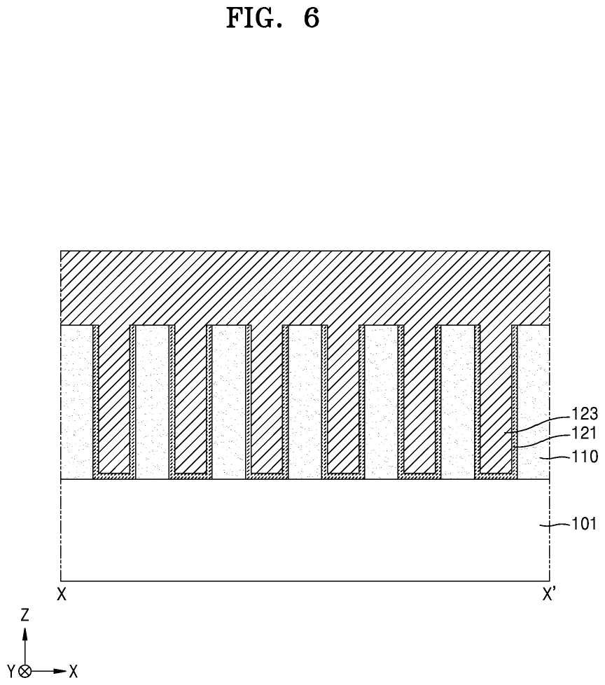

The technical feature of each of the first to sixth operations S110 to S160 is described below in detail with reference to FIGS. 6 to 16.

FIGS. 6 to 16 are cross-sectional views showing a method of manufacturing a semiconductor device in a process sequence, according to an embodiment.

Referring to FIG. 6, a semiconductor substrate 101 may be prepared.

In various embodiments, a portion of the semiconductor substrate 101 can be etched to form an active pattern FA (see FIG. 17) that protrudes from the upper surface of the semiconductor substrate 101 in a vertical direction (Z direction) and extends in a first horizontal direction (X direction), where the vertical direction (Z direction) can be perpendicular to the first horizontal direction (X direction).

After an insulating film covering the active pattern FA is formed on the semiconductor substrate 101, the insulating film may be etched to form a device isolation film 103 (see FIG. 17). The active pattern FA may protrude upward from the upper surface of the device isolation film 103 and may be thus exposed.

A gate dielectric film 121 and a gate electrode 123 may be sequentially formed on the active pattern FA of the semiconductor substrate 101. In some embodiments, the gate dielectric film 121 may include an insulating material, such as silicon oxide, and the gate electrode 123 may include a conductive material, such as metal.

In some embodiments, a lower interlayer insulating film 110 may be formed to cover both sides of the gate dielectric film 121. The lower interlayer insulating film 110 may include, for example, an insulating material, such as silicon oxide.

In some embodiments, the gate dielectric film 121 and the gate electrode 123 may be formed through a replacement process or a gate last process.

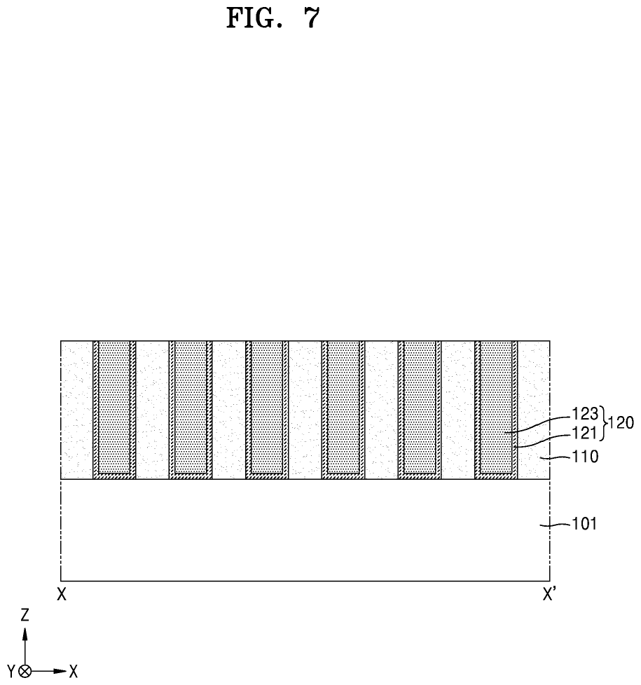

Referring to FIG. 7, a planarization process may be performed on the upper surface of the gate electrode 123, and thus, a plurality of gate structures 120 may be provided in a separate form. The upper surface of the gate electrode 123 may be coplanar with an upper surface of the lower interlayer insulating film 110 subsequent to the planarization process.

In various embodiments, source/drain regions SD (see FIG. 17) may be formed by an epitaxial growth process on active patterns FA, that are exposed from both sides of each of the plurality of gate structures 120.

The plurality of gate structures 120 may be spaced apart from each other in a first horizontal direction (X direction) on the semiconductor substrate 101 and extend in a second horizontal direction (Y direction). Also, the plurality of gate structures 120 may be arranged on the active pattern FA and the device isolation film 103.

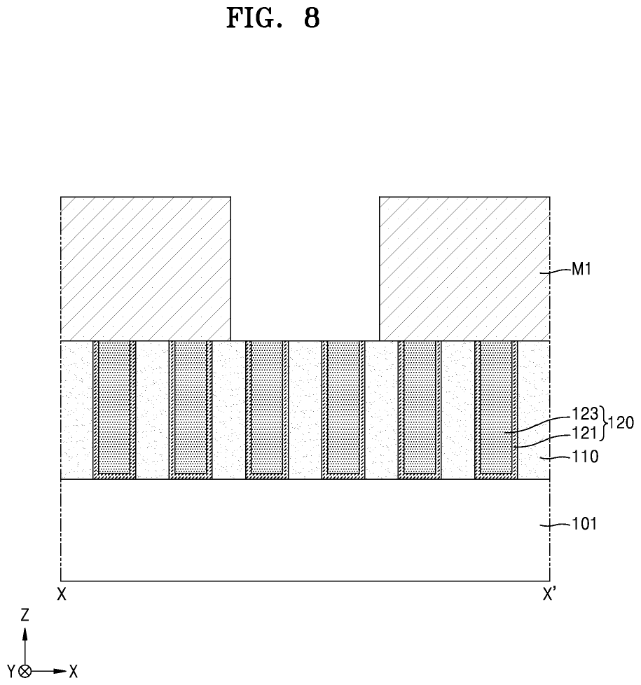

Referring to FIG. 8, a mask pattern M1 may be formed on the lower interlayer insulating film 110 and the plurality of gate structures 120.

The mask pattern M1 may include any material having an etch selectivity with respect to the lower interlayer insulating film 110 and the plurality of gate structures 120 and is not particularly limited. The mask pattern M1 may include, for example, a spin on hardmask (SOH). In order to form the mask pattern M1, a photoresist film may be formed and a photolithography process and an etch process may be performed. One or more gate structures 120 may be exposed after forming the mask pattern M1.

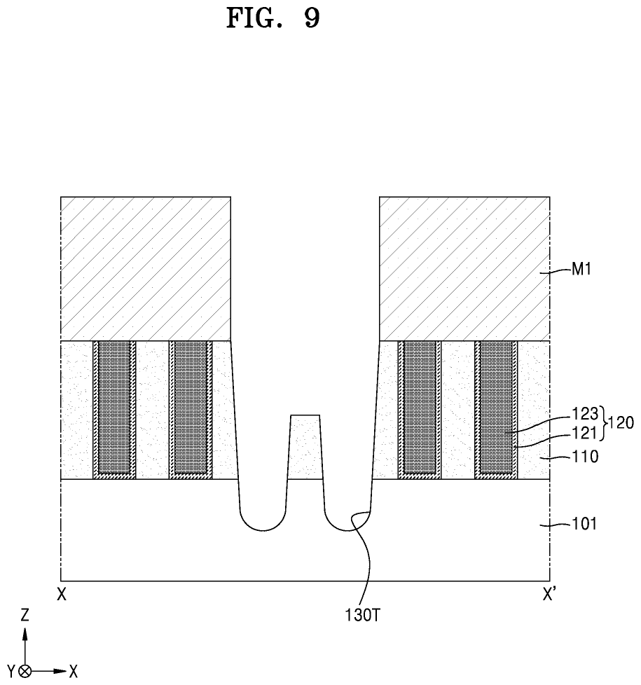

Referring to FIG. 9, a gate cut trench 130T may be formed by performing an etching process using the mask pattern M1 as an etch mask.

In various embodiments, a portion of the lower interlayer insulating film 110 and portions of the plurality of gate structures 120 can be etched to form a gate cut trench 130T that may expose at least a portion of the semiconductor substrate 101 between lower interlayer insulating films 110. The gate cut trench 130T may extend into the semiconductor substrate 101. Depending on the characteristics of a dry etching process, the gate cut trench 130T may have a tapered shape of which a width decreases toward the bottom thereof, but the embodiment is not limited thereto.

In various embodiments, the mask pattern M1 may be removed to expose the underlying features. The mask pattern M1 may be removed through ashing and stripping processes.

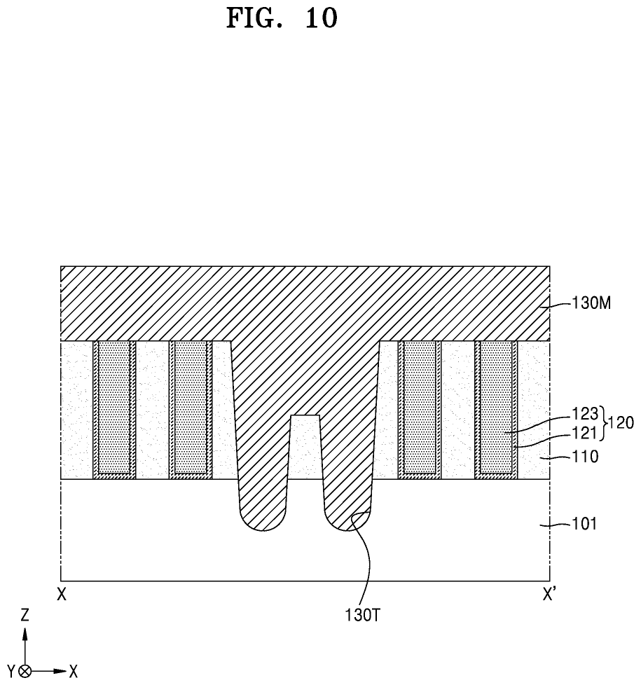

Referring to FIG. 10, a gate cut material layer 130M may be formed to fill the gate cut trench 130T and cover the upper surface of the lower interlayer insulating film 110.

The gate cut material layer 130M may include an insulating material. In some embodiments, a gate cut structure 130 may include silicon nitride (SiN), silicon oxide (SiO), silicon oxynitride (SiON), etc., but the embodiment is not limited thereto.

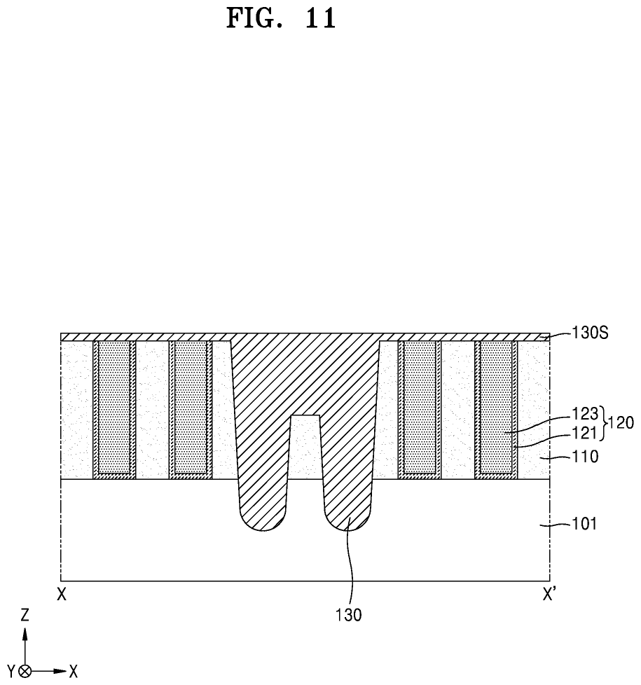

Referring to FIG. 11, most of the upper portion of the gate cut material layer 130M (see FIG. 10) may be removed by a planarization process.

Through the planarization process, the gate cut structure 130, which fills the inside of the gate cut trench 130T, and a gate cut upper layer 130S, which is positioned above the gate cut structure 130, may be formed. A portion of the gate cut material layer 130M may remain on the upper surfaces of the lower interlayer insulating films 110 and the gate structures 120 to form a gate cut upper layer 130S.

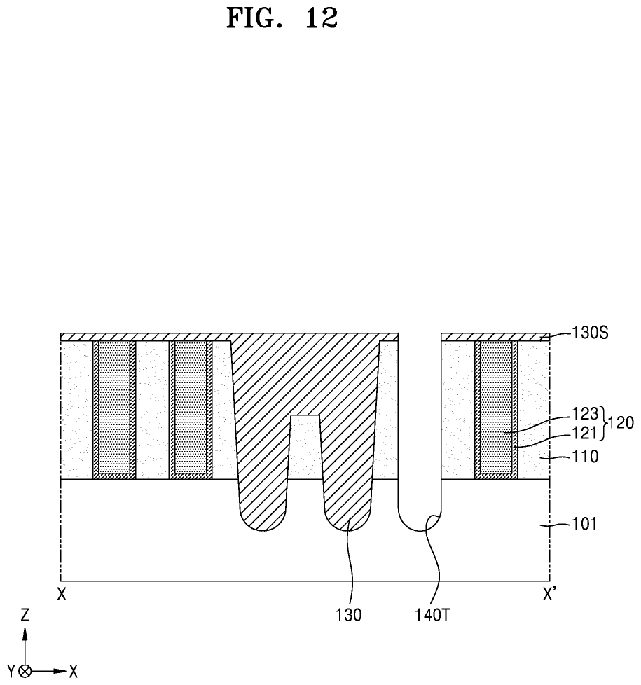

Referring to FIG. 12, a first trench 140T may be formed by removing a portion of the plurality of gate structures 120.

Specifically, a portion of the plurality of gate structures 120 and a portion of the gate cut upper layer 130S covering the portion of the plurality of gate structures 120 can be removed. The first trench 140T may be formed to expose the semiconductor substrate 101 between lower interlayer insulating films 110. The first trench 140T may be formed through a photolithography process and an etching process, which can selectively remove the portion of the plurality of gate structures 120.

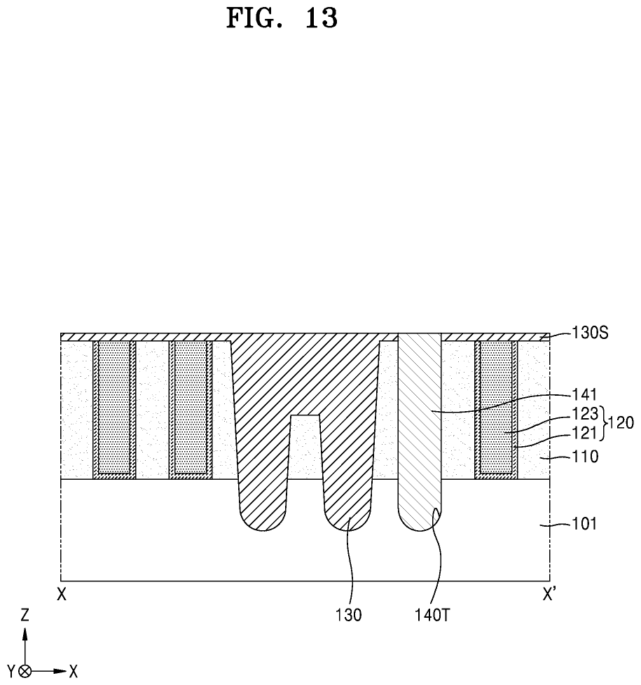

Referring to FIG. 13, a lower insulating material film 141 may be formed to fill the first trench 140T.

In various embodiments, a material constituting the lower insulating material film 141 may have an etch selectivity with respect to a material constituting the gate cut structure 130, but the embodiment is not limited thereto. The lower insulating material film 141 may be formed by a chemical vapor deposition process, a physical vapor deposition process, or an atomic layer deposition process.

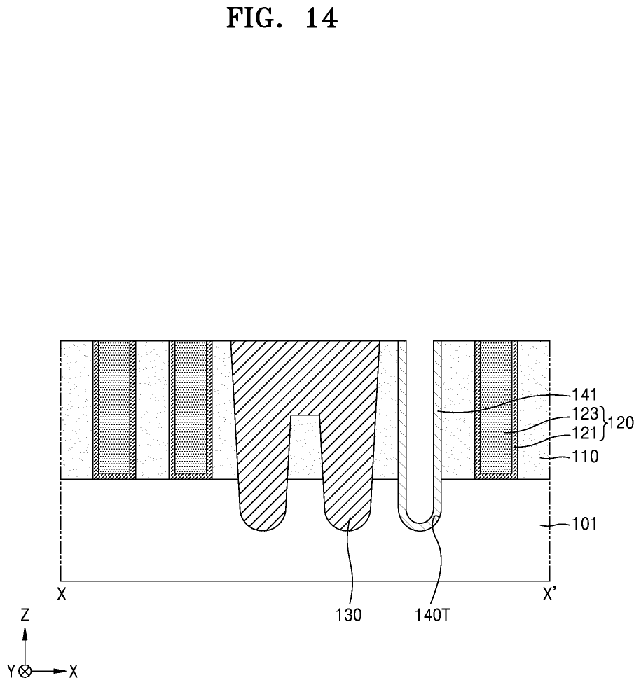

Referring to FIG. 14, portions of the gate cut upper layer 130S (see FIG. 13) and the lower insulating material film 141 may be removed by non-selective etching process.

Accordingly, the gate cut upper layer 130S (see FIG. 13) may be removed, and the lower insulating material film 141 may be conformally formed on the inner wall of the first trench 140T. Accordingly, the lower insulating material film 141 may have a U-shape inside the first trench 140T. Also, due to the non-selective etching process, the upper surfaces of the plurality of gate structures 120, the upper surface of the gate cut structure 130, and the upper surface of the lower interlayer insulating film 110 may be exposed.

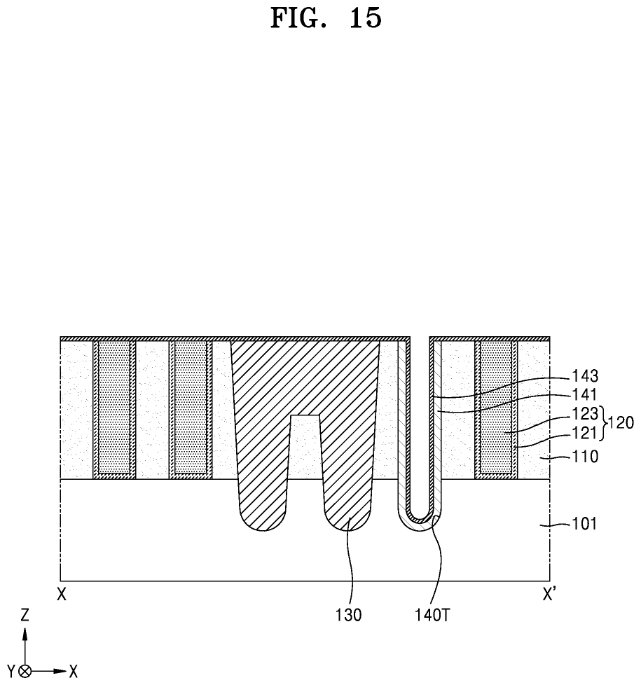

Referring to FIG. 15, an insulating liner 143 is conformally formed on the inner wall of the lower insulating material film 141, the upper surfaces of the plurality of gate structures 120, the upper surface of the gate cut structure 130, and the upper surface of the lower interlayer insulating film 110.

The insulating liner 143 may be formed by, for example, a chemical vapor deposition process or an atomic layer deposition process. However, the embodiment is not limited to these processes. The thickness of the insulating liner 143 is not particularly limited, and for example, the thickness of the insulating liner 143 may be less than the thickness of the lower insulating material film 141.

Accordingly, the insulating liner 143 may be formed to be substantially flat on both the upper surfaces of the plurality of gate structures 120 and the upper surface of the gate cut structure 130 and may have a U-shape inside the first trench 140T.

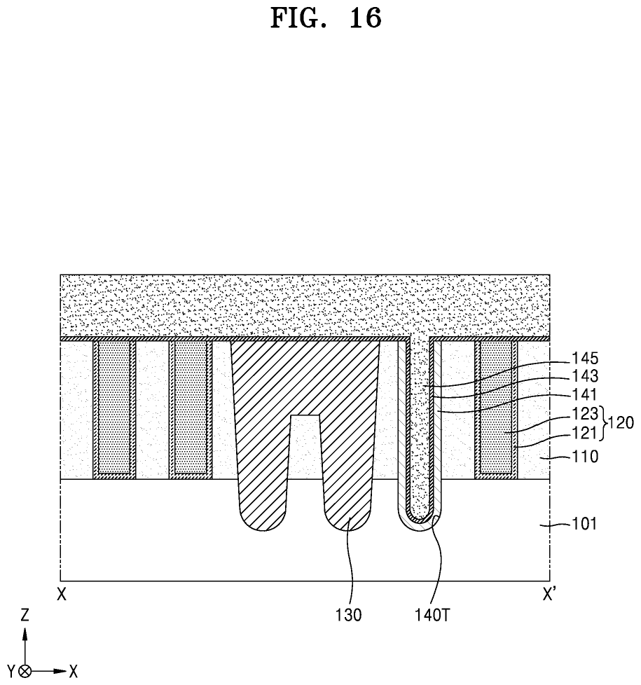

Referring to FIG. 16, an upper insulating material film 145 may be formed to fill the remaining portion of the first trench 140T.

Here, each of the lower insulating material film 141, the insulating liner 143, and the upper insulating material film 145 may include, for example, silicon nitride (SiN), silicon carbonitride (SiCN), silicon oxide (SiO), silicon oxynitride (SiON), silicon carbide (SiC), silicon oxycarbide (SiOC), silicon oxycarbonitride (SiOCN), silicon boron nitride (SiBN), silicon boron carbon nitride (SiBCN), titanium oxide (TiO), or boron nitride (BN), but the embodiment is not limited thereto.

Referring back to FIG. 2, a planarization process may be performed on the upper insulating material film 145 and an upper interlayer insulating film 150 may be formed.

Accordingly, the semiconductor device 10 according to the inventive concept, which is manufactured through the semiconductor device manufacturing method described above, is configured such that the single diffusion brake 140 has a multilayer structure therein. Therefore, stress modulation is possible by selectively controlling materials that constitute the multilayer structure, and thus, there is an effect of providing high mechanical stability and high electrical stability.

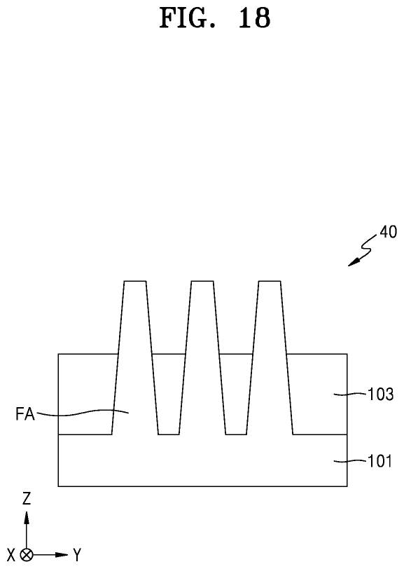

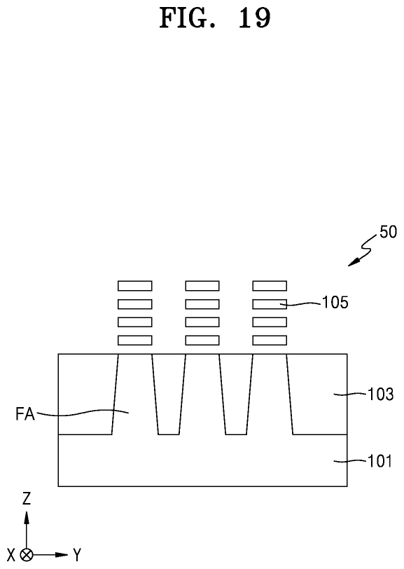

FIG. 17 is a schematic perspective view showing a semiconductor device according to an embodiment, and FIGS. 18 and 19 are cross-sectional views corresponding to an active pattern of the semiconductor device of FIG. 17.

Referring to FIGS. 17 to 19 together, at least one active pattern FA may extend in a first horizontal direction (X direction) on a semiconductor substrate 101, and the active pattern FA may cross a plurality of gate structures 120, which extend in a second horizontal direction (Y direction), to thereby form a transistor.

The plurality of gate structures 120 may be spaced apart from each other in the first horizontal direction (X direction) on the semiconductor substrate 101 and extend in the second horizontal direction (Y direction). Also, the plurality of gate structures 120 may be arranged on the active pattern FA and the device isolation film 103 above the semiconductor substrate 101.

The single diffusion brakes 140 may be spaced apart from each other in the first horizontal direction (X direction) in the semiconductor substrate 101 and extend in the second horizontal direction (Y direction). Also, the single diffusion brake 140 may pass through the device isolation film 103 and extend into the semiconductor substrate 101 to cut a source/drain region SD and/or the active pattern FA.

In a semiconductor device 40 illustrated in FIG. 18, when an active pattern FA having a fin shape extends in a first horizontal direction (X direction), a transistor formed by the active pattern FA and a gate electrode 123 may be referred to as a fin-type field effect transistor (FinFET). Here, the embodiments have been mainly described with reference to the semiconductor device 40 including the FinFET, but may also be applied to a transistor having a structure different from that of the FinFET. A fin-type active pattern FA can be disposed below a plurality of the gate structures 120.

In a semiconductor device 50 illustrated as an example in FIG. 19, an active pattern FA may include a plurality of nano sheets 105 which are spaced apart from each other in a vertical direction (Z direction) and extend in a first horizontal direction (X direction). A transistor formed by the plurality of nano sheets 105 and a gate electrode 123 may include a multi-bridge channel FET (MBCFET).

Although not illustrated, as a nano sheet for a p-type transistor and a nano sheet for an n-type transistor are separated by a dielectric wall, a semiconductor device may include a ForkFET having a structure in which the n-type and p-type transistors are closer to each other.

Also, a semiconductor device may include a vertical FET (VFET) having a structure in which source/drain regions are spaced apart from each other in a vertical direction (Z direction) with a channel region therebetween and a gate electrode surrounds the channel region.

In addition, a semiconductor device may include a complementary FET (CFET), a negative FET (NCFET), a carbon nanotube (CNT) FET, etc., and a semiconductor device may include a bipolar junction transistor and other 3-dimensional transistors.

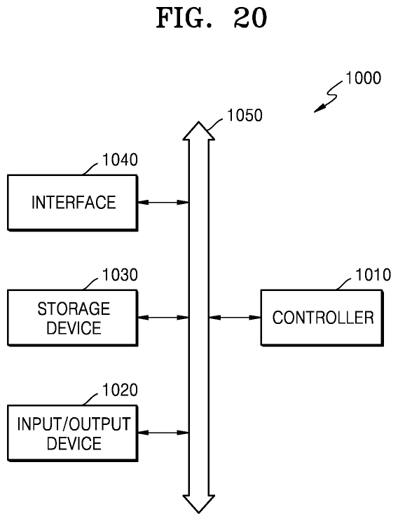

FIG. 20 is a block diagram showing a system including a semiconductor device according to an embodiment.

Referring to FIG. 20, a system 1000 includes a controller 1010, an input/output device 1020, a storage device 1030, an interface 1040, and a bus 1050.

The system 1000 may include a mobile system or a system that transmits or receives information. In some embodiments, the mobile system may include a portable computer, a web tablet, a mobile phone, a digital music player, or a memory card.

The controller 1010 can control an execution program in the system 1000, and may include a microprocessor, a digital signal processor, a microcontroller, or a device similar thereto.

The input/output device 1020 may be used to input or output data of the system 1000. The system 1000 may be connected to an external device, for example, a personal computer or a network, and exchange data with the external device using the input/output device 1020. The input/output device 1020 may include, for example, a touch screen, a touch pad, a keyboard, or a display.

The storage device 1030 may store data for operation of the controller 1010 or data processed by the controller 1010. The storage device 1030 may include any one of the semiconductor devices 10, 20, 30, 40, and 50 according to the inventive concept described above.

The interface 1040 may include a data transmission path between the system 1000 and an external device. The controller 1010, the input/output device 1020, the storage device 1030, and the interface 1040 may communicate with each other via the bus 1050.

While the inventive concept has been particularly shown and described with reference to embodiments thereof, it will be understood that various changes in form and details may be made therein without departing from the spirit and scope of the following claims.

What is claimed is:

1. A semiconductor device comprising:
a semiconductor substrate;
a plurality of gate structures which are spaced apart from each other in a first horizontal direction on the semiconductor substrate and extend in a second horizontal direction perpendicular to the first horizontal direction; and
a single diffusion brake which extends in the second horizontal direction between the plurality of gate structures and is located in a first trench having a first depth in a vertical direction,
wherein the single diffusion brake comprises:
a lower insulating material film on a side wall of the first trench;
an insulating liner extending onto upper surfaces of the plurality of gate structures along an inner wall of the lower insulating material film; and
an upper insulating material film on the insulating liner and filling an inside of the first trench.

2. The semiconductor device of claim 1, wherein the insulating liner is substantially flat on the upper surfaces of the plurality of gate structures and has a U-shape inside the first trench.

3. The semiconductor device of claim 1, wherein the lower insulating material film, the insulating liner, and the upper insulating material film comprise different materials.

4. The semiconductor device of claim 3, wherein the lower insulating material film comprises a nitride film-based material, and
the upper insulating material film comprises an oxide film-based material.

5. The semiconductor device of claim 1, wherein an inner wall of the first trench is in contact with the lower insulating material film, and
the inner wall and an upper surface of the lower insulating material film are in contact with the insulating liner.

6. The semiconductor device of claim 5, wherein an inner wall and an upper surface of the insulating liner are in contact with the upper insulating material film.

7. The semiconductor device of claim 1, further comprising a gate cut structure configured to cut portions of the plurality of gate structures,
wherein the insulating liner extends onto an upper surface of the gate cut structure.

8. The semiconductor device of claim 7, wherein a lower surface of the insulating liner is in contact with both the upper surfaces of the plurality of gate structures and the upper surface of the gate cut structure.

9. The semiconductor device of claim 1, wherein a fin-type active pattern is disposed below the plurality of the gate structures.

10. The semiconductor device of claim 1, wherein nano sheets stacked in the vertical direction are disposed below the plurality of the gate structures.

11. A semiconductor device comprising:
a semiconductor substrate;
a plurality of gate structures which are spaced apart from each other in a first horizontal direction on the semiconductor substrate and extend in a second horizontal direction perpendicular to the first horizontal direction; and
a single diffusion brake which extends in the second horizontal direction between the plurality of gate structures and is located in a first trench having a first depth in a vertical direction,
wherein the single diffusion brake comprises:
a lower insulating material film on a side wall of the first trench;
insulating liners stacked in at least two layers and extending onto upper surfaces of the plurality of gate structures along an inner wall of the lower insulating material film; and
an upper insulating material film on the insulating liners and filling an inside of the first trench.

12. The semiconductor device of claim 11, wherein the insulating liners comprise a first insulating liner located in a lower region and a second insulating liner located in an upper region, and
the first insulating liner and the second insulating liner comprise different materials.

13. The semiconductor device of claim 12, wherein the lower insulating material film comprises a silicon nitride film, and
the upper insulating material film comprises a silicon oxide film.

14. The semiconductor device of claim 12, wherein each of the first insulating liner and the second insulating liner is substantially flat on the upper surfaces of the plurality of gate structures and has a U-shape inside the first trench.

15. The semiconductor device of claim 14, further comprising a gate cut structure configured to cut portions of the plurality of gate structures,
wherein the first insulating liner and the second insulating liner extend onto an upper surface of the gate cut structure, and
a lower surface of the first insulating liner is in contact with both the upper surfaces of the plurality of gate structures and the upper surface of the gate cut structure.

16. A semiconductor device comprising:
a semiconductor substrate;
a plurality of active patterns extending in a first horizontal direction in the semiconductor substrate;
a plurality of gate structures which extend in a second horizontal direction perpendicular to the first horizontal direction, wherein the plurality of gate structures cross the plurality of active patterns in the semiconductor substrate;
a gate cut structure configured to cut portions of the plurality of gate structures in the semiconductor substrate; and
a single diffusion brake which extends between the plurality of gate structures in the second horizontal direction and is located in a first trench having a first depth in a vertical direction,
wherein the single diffusion brake comprises:
a lower insulating material film on a side wall of the first trench;
an insulating liner extending onto both upper surfaces of the plurality of gate structures and an upper surface of the gate cut structure along an inner wall of the lower insulating material film; and
an upper insulating material film on the insulating liner and filling an inside of the first trench.

17. The semiconductor device of claim 16, wherein a level of a lowermost surface of the first trench is lower than a level of an upper surface of the semiconductor substrate.

18. The semiconductor device of claim 16, wherein the insulating liner is substantially flat on both the upper surfaces of the plurality of gate structures and the upper surface of the gate cut structure and has a U-shape inside the first trench.

19. The semiconductor device of claim 18, wherein a lower surface of the insulating liner is in contact with both the upper surfaces of the plurality of gate structures and the upper surface of the gate cut structure.

20. The semiconductor device of claim 16, wherein the lower insulating material film comprises a silicon nitride material, and
the upper insulating material film comprises a silicon oxide material.
